(19) United States
(12) Patent Application Publication
(10) Pub. No.: US 2024/0035143 A1
(43) Pub. Date: Feb. 1, 2024

(54) APPARATUS AND METHOD FOR MANUFACTURING DISPLAY APPARATUS

(71) Applicant: Samsung Display Co., Ltd., Yongin-si (KR)

(72) Inventors: Sangha Park, Yongin-si (KR); Dahee Jeong, Yongin-si (KR); Eunbee Jo, Yongin-si (KR)

(73) Assignee: Samsung Display Co., Ltd., Yongin-si (KR)

(21) Appl. No.: 18/313,562

(22) Filed: May 8, 2023

(30) Foreign Application Priority Data
Jul. 27, 2022 (KR) 10-2022-0093453

(51) Int. Cl. C23C 14/04; H10K 71/16

(52) U.S. Cl. CPC C23C 14/042; H10K 71/166

(57) ABSTRACT

An apparatus for manufacturing a display apparatus includes a chamber, a mask assembly located in the chamber to face a display substrate, and including at least one deposition area, and a deposition source located in the chamber to face the mask assembly, wherein the mask assembly includes a mask frame including an opening area, at least one shield stick intersecting the opening area, and at least one mask sheet covering at least part of the opening area and at least partially overlapping the at least one shield stick, and each of the at least one mask sheet includes a first body including a hole area including pattern holes and covering the at least one deposition area, and a second body connected to the first body and fixed to the mask frame, and a maximum width of the first body is greater than a maximum width of the second body.

### CROSS-REFERENCE TO RELATED APPLICATION(S)

This application claims priority to and benefits of Korean Patent Application No. 10-2022-0093453 under 35 U.S.C. § 119, filed on Jul. 27,2022, in the Korean Intellectual Property Office (KIPO), the entire contents of which are incorporated herein by reference.

### BACKGROUND

### 1. Technical Field

One or more embodiments relate to an apparatus and method, and more particularly, to an apparatus and method for manufacturing a display apparatus.

### 2. Description of the Related Art

Recently, electronic devices have been widely used. Electronic devices have been variously used as mobile electronic devices and fixed electronic devices. Such electronic devices include display apparatuses that may provide a user with visual information such as images, videos, or the like to support various functions.

A display apparatus visually displays data and is formed by depositing various layers such as an organic layer, a metal layer, or the like. To form layers of a display apparatus, a deposition material may be deposited. For example, as a deposition material is sprayed from a deposition source, the deposition material is deposited on a substrate through a mask assembly. In case that a mask sheet is deformed or interference occurs between the mask sheet and a shield stick, the deposition material may not be deposited at a required position on the substrate, thereby degrading deposition quality.

The background described above is technology information that the inventor possessed for the derivation of the disclosure or acquired in the derivation process of the disclosure, and it may not be said that it is known technology disclosed to the general public before the filing of the disclosure.

### SUMMARY

One or more embodiments include an apparatus and method for manufacturing a display apparatus, which may prevent waves generated as a mask sheet is tensioned and may improve the deposition quality of a deposition material by preventing interference between the mask sheet and a shield stick.

However, the embodiments are merely examples, and the disclosure is not limited thereto.

Additional aspects will be set forth in part in the description which follows and, in part, will be apparent from the description, or may be learned by practice of the embodiments.

According to one or more embodiments, an apparatus for manufacturing a display apparatus includes a chamber, a mask assembly located in the chamber to face a display substrate, and including at least one deposition area, and a deposition source located in the chamber to face the mask assembly, and supplying a deposition material so that the deposition material passes through the at least one deposition area of the mask assembly and is deposited on the display substrate, wherein the mask assembly includes a mask frame including an opening area, at least one shield stick intersecting the opening area, and at least one mask sheet covering at least part of the opening area and at least partially overlapping the at least one shield stick, and each of the at least one mask sheet includes a first body including a hole area including pattern holes and covering the at least one deposition area, and a second body connected to the first body and fixed to the mask frame, and a maximum width of the first body is greater than a maximum width of the second body.

The at least one mask sheet may include an overlapping area overlapping the at least one shield stick in a plan view, and the overlapping area has a convex shape in a plan view.

The hole area includes a first hole area overlapping the at least one shield stick in a plan view, and a second hole area not overlapping the at least one shield stick in a plan view.

The first hole area may have a convex shape.

A number of pattern holes per unit area in the first hole area and a number of pattern holes per unit area in the second hole area may be substantially equal to each other.

In a plan view, sizes of pattern holes provided in the first hole area and sizes of pattern holes provided in the second hole area may be substantially equal to each other.

A number of pattern holes per unit area provided in the first hole area may gradually decrease outward.

In a plan view, sizes of pattern holes provided in the first hole area may gradually decrease outward.

A thickness of the hole area may be less than a thickness of an area where the pattern holes are not provided.

The first body may further include an outer area located outside the hole area and overlapping the at least one shield stick in a plan view, and a thickness of the hole area and a thickness of the outer area are less than a thickness of a remaining area of the first body.

In a plan view, the outer area may have a convex portion.

According to one or more embodiments, a method of manufacturing a display apparatus includes locating a display substrate and a mask assembly in a chamber, and depositing a deposition material on the display substrate by allowing the deposition material to pass through the mask assembly, wherein the mask assembly includes a mask frame including an opening area, and at least one mask sheet covering at least part of the opening area, and each of the at least one mask sheet includes a first body including a hole area including pattern holes, and a second body connected to the first body and fixed to the mask frame, and a maximum width of the first body is greater than a maximum width of the second body.

In a plan view, the first body may have a convex shape.

In a plan view, the hole area may have a convex shape.

A number of pattern holes per unit area in the hole area may be uniform.

In a plan view, sizes of the pattern holes in the hole area may be same.

A number of pattern holes per unit area in an outer portion of the hole area may be less than a number of pattern holes in a central portion of the hole area.

Sizes of pattern holes in an outer portion of the hole area may be less than sizes of pattern holes in a central portion of the hole area.

A thickness of the hole area may be less than a thickness of an area where the pattern holes are not provided.

The first body may further include an outer area located outside the hole area, and a thickness of the hole area and a thickness of the outer area may be less than a thickness of a remaining area of the first body.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a cross-sectional view schematically illustrating a display apparatus, according to an embodiment;

FIG. 2 is a perspective view schematically illustrating a mask assembly, according to an embodiment;

FIG. 3 is a plan view schematically illustrating a mask sheet, according to an embodiment;

FIGS. 4A and 4B are views schematically illustrating a method of manufacturing an apparatus for manufacturing a display apparatus, according to an embodiment;

FIG. 5 is a plan view schematically illustrating a part of a mask assembly, according to an embodiment;

FIGS. 6A to 6C are enlarged views schematically illustrating a portion A of FIG. 3, according to an embodiment;

FIGS. 7A to 7C are cross-sectional views schematically illustrating a portion I-I′ of FIG. 3, according to an embodiment;

FIG. 8 is a plan view schematically illustrating a mask sheet, according to another embodiment;

FIGS. 9A and 9B are cross-sectional views schematically illustrating a portion II-II′of FIG. 8, according to another embodiment;

FIG. 10 is a plan view schematically illustrating a display apparatus manufactured by using a method of manufacturing a display apparatus, according to an embodiment; and

FIG. 11 is a cross-sectional view schematically illustrating a display apparatus manufactured by using a method of manufacturing a display apparatus, according to an embodiment.

### DETAILED DESCRIPTION OF THE EMBODIMENTS

For the purposes of this disclosure, the phrase “at least one of A and B” or “at least one A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Although the terms “first”, “second”, and the like may be used herein to describe various types of elements, these elements should not be limited by these terms. These terms are used to distinguish one element from another element. Thus, a first element discussed below could be termed a second element without departing from the teachings of the disclosure.

In the specification and the claims, the term “and/or” is intended to include any combination of the terms “and” and “or” for the purpose of its meaning and interpretation. For example, “A and/or B” may be understood to mean “A, B, or A and B” . The terms “and” and “or” may be used in the conjunctive or disjunctive sense and may be understood to be equivalent to “and/or”.

The terminology used herein is for the purpose of describing particular embodiments and is not intended to be limiting. As used herein, the singular forms, “a”, “an”, and “the” are intended to include the plural forms as well, unless the context clearly indicates otherwise. Moreover, the terms “comprises”, “comprising”, “includes”, and/or “including”, when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially”, “about”, and other similar terms are used as terms of approximation and not as terms of degree, and, as such, are utilized to account for inherent deviations in measured, calculated, and/or provided values that would be recognized by one of ordinary skill in the art.

When an element, such as a layer, is referred to as being “on”, “connected to,” or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. It may also be understood that if one part and another part are connected, they may or may not be integral with each other.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Sizes of components in the drawings may be exaggerated or contracted for convenience of explanation. For example, because sizes and thicknesses of elements in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

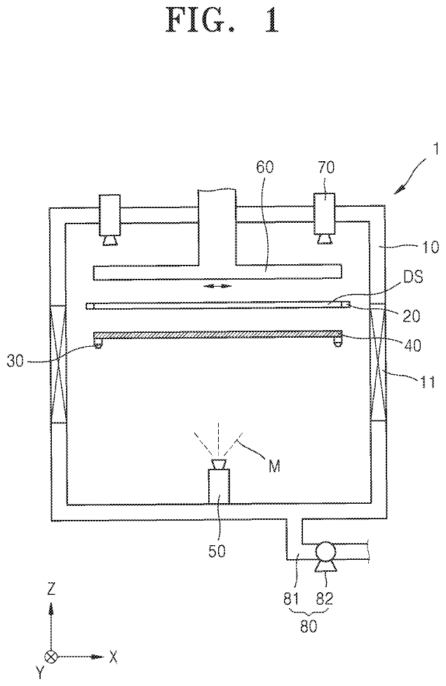

FIG. 1 is a cross-sectional view schematically illustrating an apparatus for manufacturing a display apparatus, according to an embodiment.

An apparatus 1 for manufacturing a display apparatus may include a chamber 10, a first support 20, a second support 30, a mask assembly 40, a deposition source 50, a magnetic force part 60, a vision part 70, and a pressure control part 80.

The chamber 10 may have an inner space, and a display substrate DS and the mask assembly 40 may be accommodated in the chamber 10. A part of the chamber 10 may be opened, and a gate valve 11 may be provided at an opening portion of the chamber 10. The opening portion of the chamber 10 may be opened or closed according to an operation of the gate valve 11.

display substrate DS may refer to the display substrate DS under manufacturing of a display apparatus, in which at least one of an organic layer, an inorganic layer, and a metal layer may be deposited on a substrate 100 described below. As another example, the display substrate DS may be the substrate 100 on which any of an organic layer, an inorganic layer, and a metal layer is not yet deposited.

The first support 20 may support the display substrate DS. The first support 20 may be of a plate type fixed in the chamber 10. In another embodiment, the first support 20 may be of a shuttle type on which the display substrate DS is seated and that is linearly movable in the chamber 10. In another embodiment, the first support 20 may include an electrostatic chuck or an adhesive chuck that is fixed to the chamber 10 or is located in the chamber 10 to be movable in the chamber 10.

The second support 30 may support the mask assembly 40. The second support 30 may be located in the chamber 10. The second support 30 may finely adjust a position of the mask assembly 40. The second support 30 may include a separate driver or alignment part to move the mask assembly 40 in different directions.

In another embodiment, the second support 30 may be of a shuttle type. The mask assembly 40 may be seated on the second support 30, and the second support 30 may move the mask assembly 40. For example, the second support 30 may move to an outside of the chamber 10, may allow the mask assembly 40 to be seated thereon, and may enter the chamber 10 from the outside of the chamber 10.

In an embodiment, the first support 20 and the second support 30 may be integral with each other. The first support 20 and the second support 30 may each include a movable shuttle. The first support 20 and the second support 30 may include a structure for fixing the mask assembly 40 and the display substrate DS in a state where the display substrate DS is seated on the mask assembly 40, and may linearly move the display substrate DS and the mask assembly 40 at the same time.

However, for convenience of explanation, the following will be described assuming that the first support 20 and the second support 30 are formed to be distinguished from each other and located at different positions, and the first support 20 and the second support 30 are located in the chamber 10.

The mask assembly 40 may be located in the chamber 40 to face the display substrate DS. A deposition material M may pass through the mask assembly 40 and may be deposited on the display substrate DS.

The deposition source 50 may face the mask assembly 40, and may supply the deposition material M so that the deposition material M passes through a deposition area EA of the mask assembly 40 and is deposited on the display substrate DS. The deposition source 50 may vaporize or sublimate the deposition material M by applying heat to the deposition material M. The deposition source 50 may be located in the chamber 10 to be fixed in the chamber 10 or to be linearly movable in a direction.

The magnetic force part 60 may be located in the chamber 10 to face the display substrate DS and/or the mask assembly 40. The magnetic force part 60 may apply a force to the mask assembly 40 toward the display substrate DS by applying a magnetic force to the mask assembly 40. The magnetic force part 60 may prevent sagging of a mask sheet 44 and may cause the mask sheet 44 to be adjacent to the display substrate DS. Also, the magnetic force part 60 may maintain a uniform interval between the mask sheet 44 and the display substrate DS.

The vision part 70 may be located in the chamber 10, and may obtain an image of positions of the display substrate DS and the mask assembly 40. The vision part 70 may include a camera for photographing the display substrate DS and the mask assembly 40. The positions of the display substrate DS and the mask assembly 40 may be identified based on the image obtained by the vision part 70, and deformation of the mask assembly 40 may be identified based on the image obtained by the vision part 70. Also, based on the image, the position of the display substrate DS on the first support 20 may be finely adjusted, or the position of the mask assembly 40 on the second support 30 may be finely adjusted. However, the following will be described in detail assuming that the positions of the display substrate DS and the mask assembly 40 are aligned with each other by finely adjusting the position of the mask assembly 40 on the second support 30.

The pressure control part 80 may be connected to the chamber 10 and may adjust a pressure in the chamber 10. For example, the pressure control part 80 may adjust a pressure in the chamber 10 to be a same as or similar (or close) to an atmospheric pressure. Also, the pressure control part 80 may adjust a pressure in the chamber 10 to be the same as or similar to a pressure in a vacuum state.

The pressure control part 80 may include a connection pipe 81 connected to the chamber 10 and a pump 82 provided on the connection pipe 81. According to an operation of the pump 82, external air may be introduced through the connection pipe 81, or gas in the chamber 10 may be guided to the outside through the connection pipe 81.

In a method of manufacturing a display apparatus (not shown) by using the apparatus 1 for manufacturing a display apparatus, first, the display substrate DS may be prepared.

The pressure control part 80 may maintain a pressure in the chamber 10 to be the same as or similar to the atmospheric pressure, and the gate valve 11 may operate to open the opening portion of the chamber 10.

The display substrate DS may be introduced from the outside into the chamber 10. The display substrate DS may be loaded into the chamber 10 in various ways. For example, the display substrate DS may be loaded from the outside of the chamber 10 into the chamber 10 through a robot arm or the like located outside the chamber 10. In another embodiment, in case that the first support 20 is of a shuttle type, the first support 20 may be carried from the chamber 10 to the outside of the chamber 10, and then, the display substrate DS may be seated on the first support 20 by the robot arm or the like located outside the chamber 10 and the first support 20 may be introduced from the outside of the chamber 10 into the chamber 10.

The mask assembly 40 may be located in the chamber 10 as described above. In another embodiment, the mask assembly 40 may be loaded from the outside of the chamber 10 into the chamber 10, in a manner identical or similar to that of the display substrate DS.

In case that the display substrate DS is loaded into the chamber 10, the display substrate DS may be seated on the first support 20. The vision part 70 may obtain an image of positions of the display substrate DS and the mask assembly 40. The positions of the display substrate DS and the mask assembly 40 may be identified based on the image obtained by the vision part 70. The apparatus 1 for manufacturing a display apparatus may include a separate controller (not shown) and may identify the positions of the display substrate DS and the mask assembly 40.

In case that the positions of the display substrate DS and the mask assembly 40 are completely identified, the second support 30 may finely adjust the position of the mask assembly 40.

The deposition source 50 may operate to supply the deposition material M to the mask assembly 40, and the deposition material M passing through pattern holes of the mask sheet 40 may be deposited on the display substrate DS. The deposition source 50 may move in parallel with respect to the display substrate DS and the mask assembly 40, or the display substrate DS and the mask assembly 40 may move in parallel with respect to the deposition source 50. For example, the deposition source 50 may move relatively to the display substrate DS and the mask assembly 40. The pump 82 may maintain a pressure in the chamber 10 to be a same as or similar to a pressure in vacuum state, by sucking gas in the chamber 10 and discharging the gas to the outside.

As described above, the deposition material M supplied by the deposition source 50 may pass through the mask assembly 40 and may be deposited on the display substrate DS, to form at least one of layers, for example, an organic layer, an inorganic layer, and a metal layer, stacked each other in a display apparatus described below.

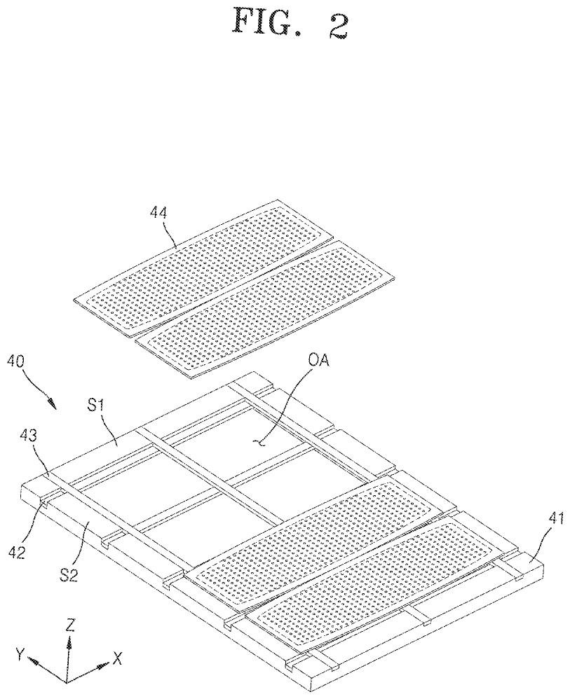

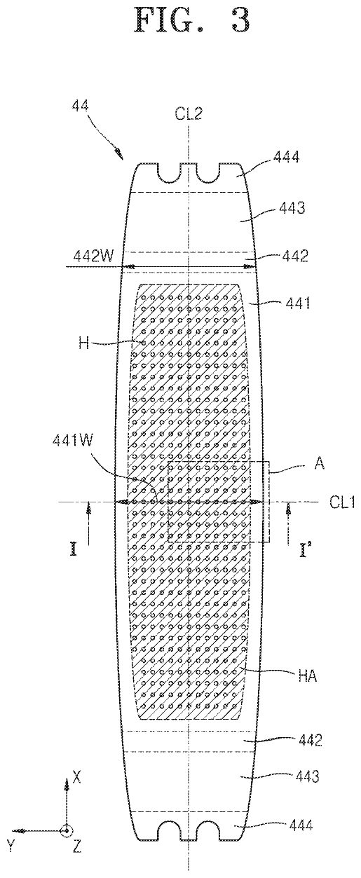

FIG. 2 is a perspective view schematically illustrating a mask assembly, according to an embodiment. FIG. 3 is a plan view schematically illustrating a mask sheet, according to an embodiment.

Referring to FIGS. 2 and 3, the mask assembly 40 may include a mask frame 41, a shield stick 42, a support stick 43, and the mask sheet 44. FIG. 3 illustrates a state before the mask sheet 44 is cut.

The mask frame 41 may be formed by connecting sides, and may include an opening area OA defined by the sides. For example, the opening area OA may be surrounded by the sides, and the opening area OA may be formed by penetrating the center of the mask frame 41.

The mask frame 41 may be a quadrangular frame according to an embodiment. A shape of the mask frame 41 is not limited thereto, and may be any of various polygonal shapes. For convenience of explanation, the following will be described assuming that the mask frame 41 is a quadrangular frame.

In case that the mask frame 41 is a quadrangular frame, sides may include a first side S1 extending in a first direction (e.g., an X axis direction of FIG. 2) and a second side S2 extending in a second direction (e.g., a Y axis direction of FIG. 2) intersecting the first direction. A pair of first sides S1 may face each other, a pair of second sides S2 may face each other, and the pair of first sides S1 and the pair of second sides S2 may be connected to each other. In an embodiment, the first side S1 may be a short side, and the second side S2 may be a long side. However, the disclosure is not limited thereto, and the first side S1 may be a long side and the second side S2 may be a short side, or lengths of the first side S1 and the second side S2 may be substantially equal to each other. For convenience of explanation, the following will be described assuming that the first side S1 is a short side and the second side S2 is a long side.

The shield stick 42 may extend in the first direction, for example, the X axis direction, as shown in FIG. 2, to cross (or intersect) the opening area OA. For example, grooves in which both end portions of the shield stick 42 are accommodated may be provided in the mask frame 41. However, this is merely an example, and a separate groove may not be provided in the mask frame 41, and the shield stick 42 may be located in the mask frame 41. The shield stick 42 may be located between mask sheets 44, and may shield the deposition material M from passing between two adjacent mask sheets 44. Shield sticks 42 may be provided, and may be spaced apart from each other in the second direction, for example, the Y axis direction, as shown in FIG. 2 to be parallel to each other.

The support stick 43 may extend in the second direction, for example, the Y axis direction, as shown in FIG. 2, to cross the opening area OA. The support stick 43 may intersect the shield stick 42 in the opening area OA and may be located over the shield stick 42. For example, grooves in which both end portions of the support stick 43 are accommodated may be located in the mask frame 41. However, this is merely an example, and a separate groove may not be located in the mask frame 41 and the support stick 43 may be located on the mask frame 41. The support stick 43 may support the mask sheet 44 in the opening area OA, and may prevent sagging of the mask sheet 44.

The mask sheet 44 may be provided in a tensioned state on the mask frame 41. At least a part of the opening area OA at the center of the mask frame 41 may be covered by the mask sheet 44. In an embodiment, at least one mask sheet 44 may be provided. In case that two or more mask sheets are provided, the mask sheets 44 may be located on the mask frame 41 to be parallel to each other. For example, the mask sheets 44 may be arranged parallel to each other in the second direction (e.g., the Y axis direction of FIG. 2). Each of the mask sheets 44 may longitudinally extend in the first direction (e.g., the X axis direction of FIG. 2). Both end portions of the mask sheet 44 may be fixed to the mask frame 41 by using, for example, welding.

In an embodiment, the mask sheet 44 may include a first body 441, a second body 442, a third body 443, and a fourth body 444. In an embodiment, both end portions of the mask sheet 44 may be symmetrical in the first direction. For convenience of explanation, an end portion, for example, an end portion in a +X axis direction of FIG. 3, will be mainly described.

The first body 441 may include a hole area HA having pattern holes H. The pattern hole H may be a through-hole formed to allow a deposition material to pass through the mask sheet 44. A deposition material passing through the first body 441 may be deposited on the display substrate DS. The pattern hole H may be formed in a pattern corresponding to a deposition pattern required by the display substrate DS.

The second body 442 may be located on both end portions of the first body 441 in the first direction (e.g., the X axis direction of FIG. 3). The second body 442 may be an area that is welded to fix the mask sheet 44 to the mask frame 41 after the fourth body 444 described below is tensioned (or stretched). In an embodiment, the mask sheet 44 may be welded to the mask frame 41 by using laser spot welding in the second body 442.

The third body 443 may be located on both end portions of the second body 442 in the first direction (e.g., the X axis direction of FIG. 3). After the mask sheet 44 is welded to the mask frame 41, the third body 443 may be cut. As the third body 443 is cut, the fourth body 444 described below may be removed.

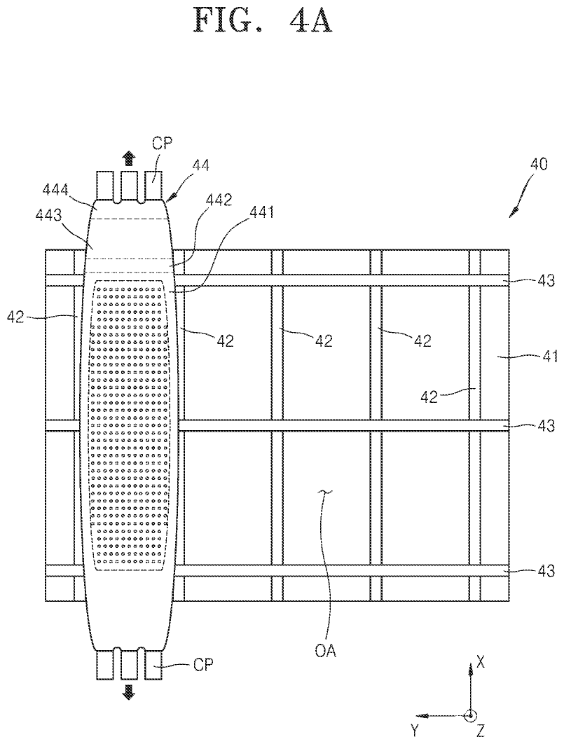

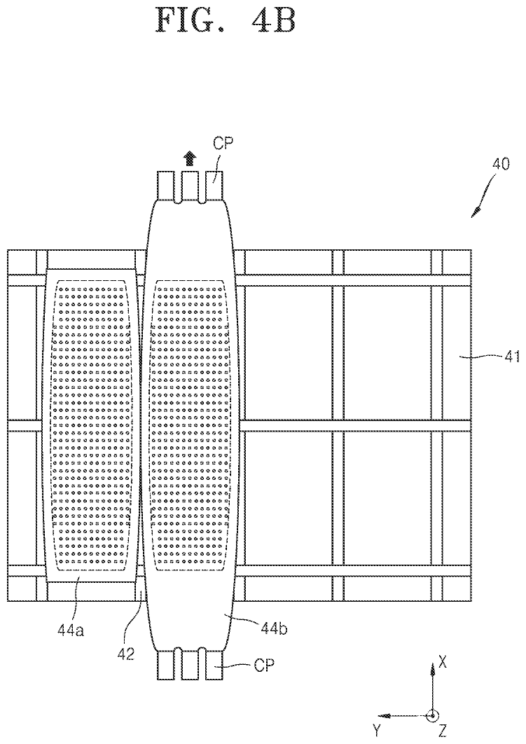

The fourth body 444 may be located on both end portions of the third body 443 in the first direction (e.g., the X axis direction of FIG. 3). The fourth body 444 may be an area that is held by a clamping device (e.g., a clamping device CP of FIG. 4A) to tension the mask sheet 44. After the mask sheet 44 is welded to the mask frame 41, the fourth body 444 may be removed.

For example, the mask sheet 44 may have a symmetrical shape about a horizontal central axis CL1 and a vertical central axis CL2. However, this is merely an example, and considering the purpose of use and a relationship with other elements, the mask sheet 44 may have any of various shapes.

FIGS. 4A and 4B are views schematically illustrating a method of manufacturing an apparatus for manufacturing a display apparatus, according to an embodiment.

A method of manufacturing an apparatus for manufacturing a display apparatus (e.g., the apparatus 1 for manufacturing a display apparatus of FIG. 1) by using the mask sheet 44 will be described with reference to FIGS. 4A and 4B. The mask sheet 44 may be used by the apparatus for manufacturing a display apparatus (e.g., the apparatus 1 for manufacturing a display apparatus) to manufacture a display apparatus. For convenience of explanation, although an end portion of the mask sheet 44 in the +X axis direction of FIG. 4A will be mainly described, a same process may be performed on an end portion in a −X axis direction of FIG. 4A.

In detail, the mask sheet 44 may be located to cover the opening area OA of the mask frame 41. The first body 441 of the mask sheet 44 may be located to correspond to the opening area OA. The second body 442, the third body 443, and the fourth body 444 may be located outside the opening area OA of the mask frame 41, and may be supported by the mask frame 41.

The fourth body 444 may be clamped by the clamping device CP, and the mask sheet 44 may be tensioned in the first direction (e.g., the X axis direction of FIG. 4A. The first direction in which the mask sheet 44 is tensioned may correspond to a longitudinal direction of the mask sheet 44.

The mask sheet 44 that is tensioned may be welded to the mask frame 41 in the second body 442. The second body 442 may be located adjacent to the opening area OA of the mask frame 41. In an embodiment, the mask sheet 44 may be welded to the mask frame 41 by using laser spot welding.

The mask sheet 44 may be cut at the third body 443 to remove the fourth body 444. As such, the fourth body 444 may be removed after tensile welding, and both end portions may be located inside a circumference of the mask frame 41 as shown in FIG. 4B. Also, because the fourth body 444 is located outside the second body 442 (i.e., in the X axis direction of FIG. 4A) and is removed, in case that mask sheets 44 are located, interference with other adjacent mask sheets 44 may be prevented.

Referring to FIG. 4B, in case that mask sheets 44 are located, in an embodiment, the mask sheet 44 may be divided into a first mask sheet 44a and a second mask sheet 44b. After the first mask sheet 44a is tensile welded and is completely cut, the second mask sheet 44b may be located parallel to the first mask sheet 44a. The second mask sheet 44b may be located parallel to the first mask sheet 44a in a direction (e.g., the Y axis direction of FIG. 4B) intersecting a longitudinal direction of the first mask sheet 44a (i.e., the X axis direction of FIG. 4B). Similar to the first mask sheet 44a, the second mask sheet 44b may be tensioned, welded, and cut.

Although the first mask sheet 44a and the second mask sheet 44b contact each other in FIG. 4B, this is merely an example, and the first mask sheet 44a and the second mask sheet 44b may be spaced apart from each other by a certain interval with the shield stick 42 therebetween.

The mask assembly 40 manufactured in this way may be completed as shown in FIG. 2, and the mask assembly 40 may be used for deposition of a display apparatus as described above.

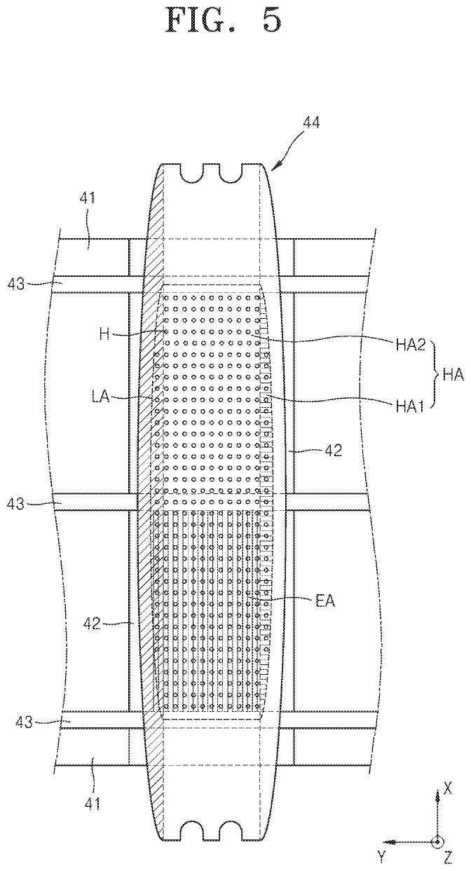

FIG. 5 is a plan view schematically illustrating a part of a mask assembly, according to an embodiment.

Referring to FIG. 5, the mask assembly 40 may include at least one deposition area EA through which a deposition material (e.g., the deposition material M of FIG. 1) passes. The deposition area EA may be surrounded by the shield stick 42 and the support stick 43. The deposition material M supplied by a deposition source (e.g., the deposition source 50 of FIG. 1) may pass through the deposition area EA of the mask assembly 40 and may be deposited on the display substrate DS.

The mask sheet 44 may cover at least one deposition area EA. In a plan view, the mask sheet 44 may include an overlapping area LA overlapping the shield stick 42. The overlapping area LA may be located on both end portions of the mask sheet 4 in the Y axis direction as shown in FIG. 5. A maximum width 441W of the first body 441 of the mask sheet 44 may be greater than a maximum width 442W of the second body 442 (see, e.g., FIG. 3). For example, in a plan view, the overlapping area LA may have a convex shape. The overlapping area LA located on an end portion of the mask sheet 44 in a +Y axis direction may have a convex shape in the +Y axis direction, and the overlapping area LA located on an end portion of the mask sheet 44 in a −Y axis direction may have a convex shape in the −Y axis direction.

In this structure, the mask sheet 44 may maintain a width of the fourth body 444 and may increase the area of the overlapping area LA. Because the width of the fourth body 444 is maintained, the number and shape of a clapping device (e.g., the clamping device CP of FIG. 4A) may be maintained. Also, waves (or wrinkles) generated due to an increase in the width of the fourth body 444 may be prevented. In a process of cleaning the mask assembly 40, as the mobility of the shield stick 42 increases, an interference phenomenon that a part of the shield stick 42 is raised above the mask sheet 44 may occur. Because the area of the overlapping area LA of the mask sheet 44 is large, such a phenomenon may be prevented.

The hole area HA of the first body 441 may cover at least one deposition area EA. In this structure, the deposition material M may pass through pattern holes provided in the hole area HA. In a plan view, the hole area may include a first hole area HA1 overlapping the shield stick 42 and a second hole area HA2 not overlapping the shield stick 42.

The first hole area HA1 may be located on both end portions of the second hole area HA2 in the Y axis direction as shown in FIG. 5. The first hole area HA1 may have a shape corresponding to the overlapping area LA. For example, in a plan view, in case that the overlapping area LA has a convex shape, the first hole area HA1 may have a convex shape. The first hole area HA1 located on an end portion of the second hole area HA2 in the +Y axis direction may have a convex shape in the +Y axis direction, and the first hole area HA1 located on an end portion of the second hole area HA2 in the −Y axis direction may have a convex shape in the −Y axis direction. In this structure, waves (or wrinkles) may be prevented from being generated in the mask sheet 44 due to a physical property difference between the hole area HA and an area where the pattern hole H is not provided.

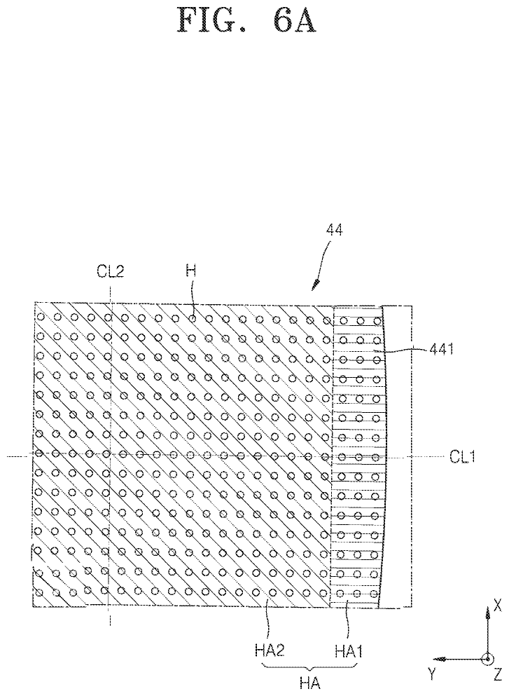

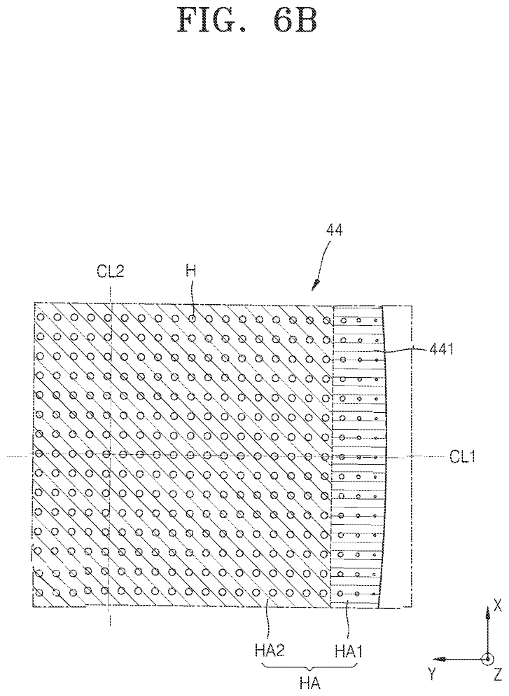

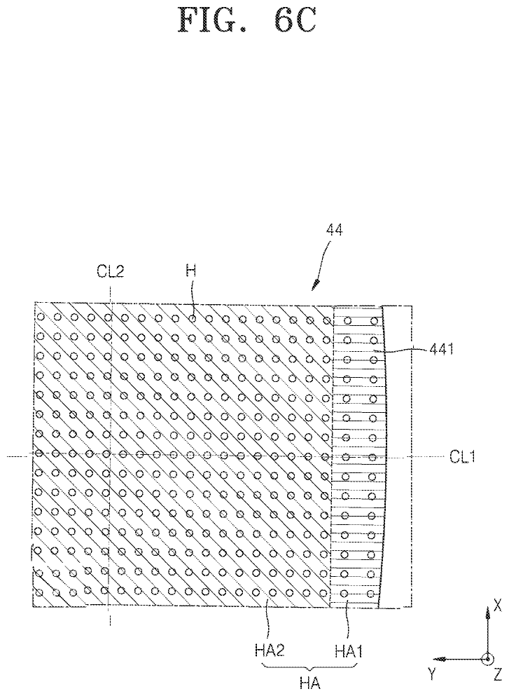

FIGS. 6A through 6C are enlarged views schematically illustrating a portion A of FIG. 3, according to an embodiment.

Referring to FIGS. 6A through 6C, the pattern holes H may be provided in the hole area HA in any of various shapes and arrangements.

For example, as shown in FIG. 6A, the number of pattern holes H per unit area in the hole area HA may be uniform. For example, the number of pattern holes H per unit area in the first hole area HA1 and the number of pattern holes H per unit area in the second hole area HA2 may be substantially equal to each other. Also, in a plan view, sizes of the pattern holes H in the hole area HA may be substantially equal to each other. For example, in a plan view, sizes of the pattern holes H provided in the first hole area HA1 and sizes of the pattern holes H provided in the second hole area HA2 may be substantially equal to each other.

In another embodiment, as shown in FIG. 6B, in a plan view, sizes of the pattern holes H provided in the first hole area HA1 may gradually decrease outward. For example, sizes of the pattern holes H in an outer portion of the hole area HA may be less than those in a central portion of the hole area HA. For example, in FIG. 6B, sizes of the pattern holes H provided in the first hole area HAl located on the right of the second hole area HA2 may gradually decrease in the −Y axis direction.

In another embodiment, as shown in FIG. 6C, the number of pattern holes H per unit area provided in the first hole area HA1 may gradually decrease outward. For example, the number of pattern holes H per unit area in an outer portion of the hole area HA may be less than that in a central portion of the hole area HA. For example, in FIG. 6C, the number of pattern holes H per unit area provided in the first hole area HAl located on the right of the second hole area HA2 may gradually decrease in the −Y axis direction.

In the structure of FIG. 6B or 6C, the first hole area HA1 may reduce a sharp physical property difference between the second hole area HA2 and an area where the pattern hole H is not provided. Accordingly, waves (or wrinkles) may be prevented from being generated in the mask sheet 44 due to a physical property difference between the hole area HA and the area where the pattern hole H is not provided.

FIGS. 6A through 6C illustrate only a portion of the mask sheet 44 for convenience of explanation, and sizes and an arrangements of the pattern holes H may be symmetrical about the horizontal central axis CL1 and the vertical central axis CL2.

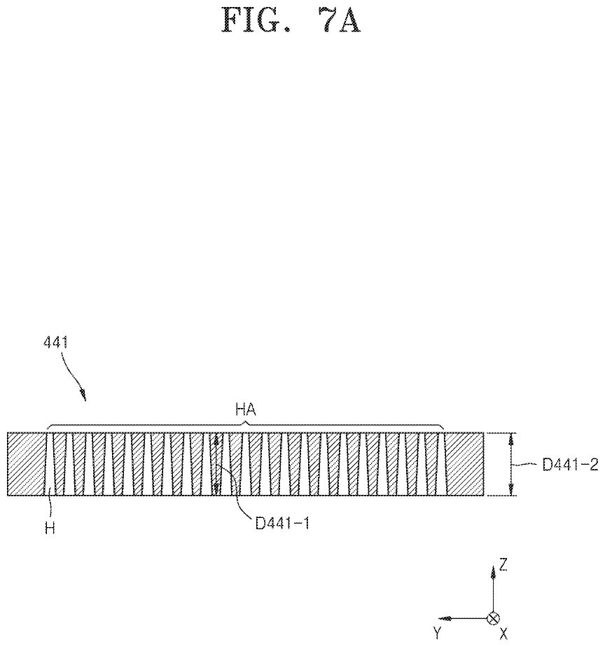

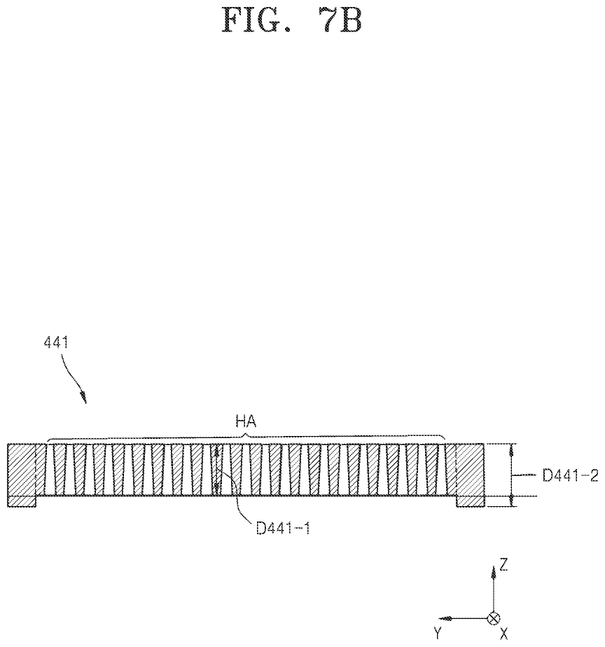

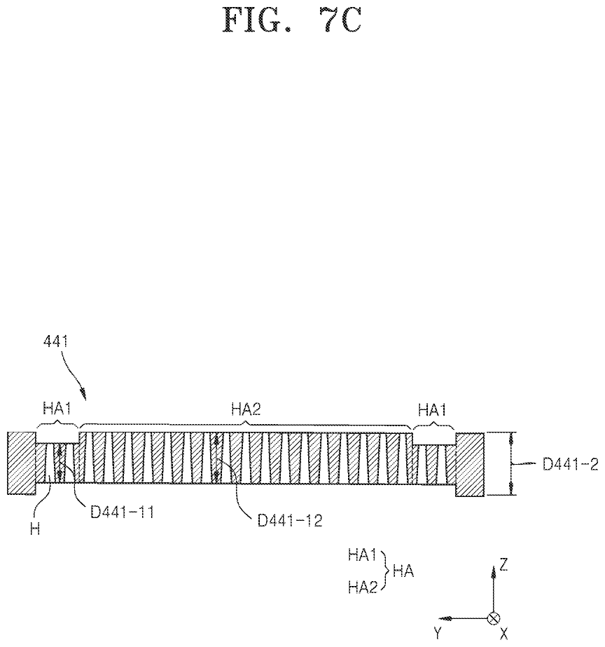

FIGS. 7A through 7C are cross-sectional views schematically illustrating a portion I-I′ of FIG. 3, according to an embodiment.

Referring to FIGS. 7A through 7C, a cross-section of the first body 441 may have any of various shapes.

For example, as shown in FIG. 7A, a thickness D441-1 of the hole area HA and a thickness D441-2 of an area where the pattern hole H is not provided may be substantially equal to each other. For example, a cross-sectional shape of the first body 441 may be a rectangular shape.

In another embodiment, as shown in FIG. 7B, the thickness D441-1 of the hole area HA may be less than the thickness D441-2 of the area where the pattern hole H is not provided. However, a surface of the first body 441 facing the display substrate DS may be a flat surface. Accordingly, the first body 441 may be located not to cause a gap between hole area HA and the display substrate DS.

For example, as shown in FIG. 7B, a surface of the first body 441 may be recessed. For example, a surface of the first body 441 in a −Z axis direction may be recessed.

In another embodiment, as shown in FIG. 7C, a thickness D441-11 of the first hole area HA1 and a thickness D441-12 of the second hole area HA2 may be less than a thickness D441-2 of the area where the pattern hole H is not provided. However, top surfaces of the second hole area HA2 and the area where the pattern hole H is not provided (e.g., surfaces in a +Z axis direction) may form a same plane. Accordingly, the first body 441 may be located not to cause a gap between the second hole area HA2 and the display substrate DS.

For example, as shown in FIG. 7C, the thickness D441-12 of the second hole area HA2 may be less than the thickness D441-2 of the area where the pattern hole H is not provided, and the thickness D441-11 of the first hole area HA1 may be less than the thickness D441-12 of the second hole area HA2.

In the structure of FIGS. 7B and 7C, because there is a thickness difference between the hole area HA and the area where the pattern hole H is not provided, waves (or wrinkles) may be prevented from being generated in a mask sheet (e.g., the mask sheet 44 of FIG. 5).

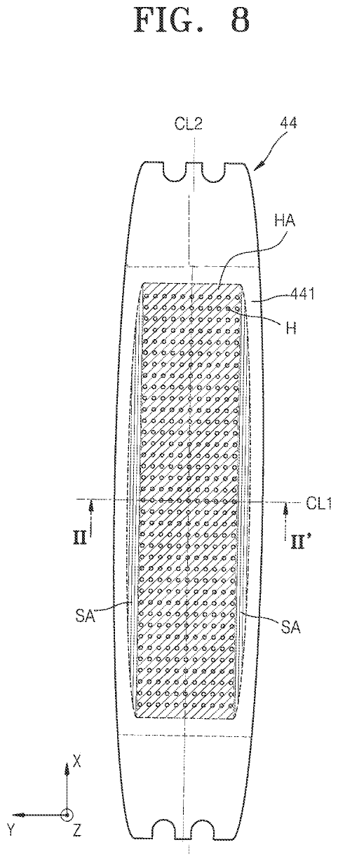

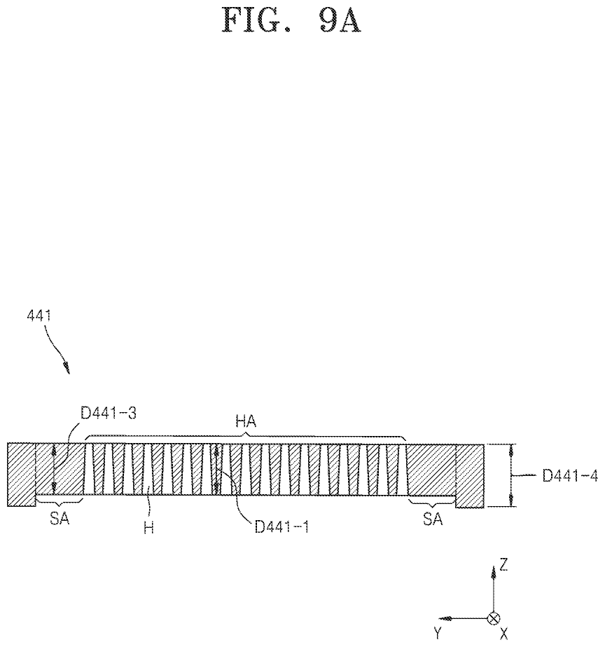

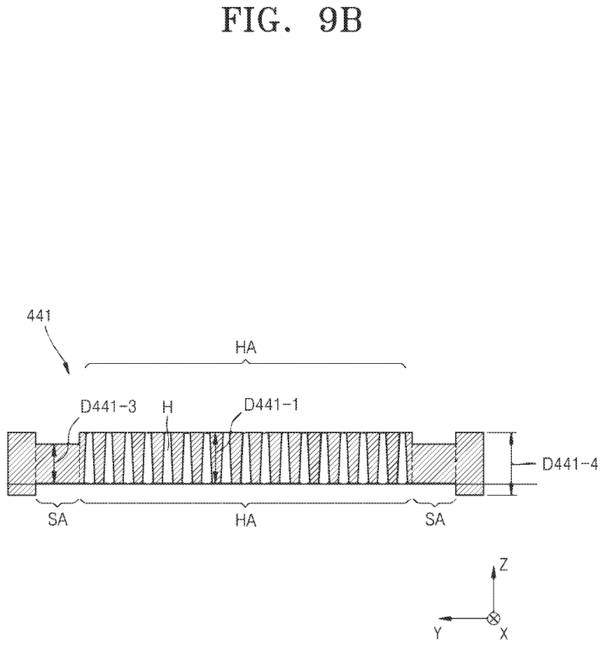

FIG. 8 is a plan view schematically illustrating a mask sheet, according to another embodiment. FIGS. 9A and 9B are cross-sectional views schematically illustrating a portion II-II′ of FIG. 8, according to another embodiment. For convenience of explanation, the same description as that made above will be omitted.

Referring to FIG. 8, the first body 441 may further include an outer area SA located outside the hole area HA and overlapping a shield stick (e.g., the shield stick 42 of FIG. 5), in addition to the hole area HA. The outer area SA may be an area where the pattern hole H is not provided. The outer area SA may be located on both end portions of the hole area HA in the Y axis direction as shown in FIG. 8. For example, in a plan view, the outer area SA may have a convex shape. The outer area SA located on an end portion of the hole area HA in the +Y axis direction may have a convex shape in the +Y axis direction, and the outer area SA located on an end portion of the hole area HA in the −Y axis direction may have a convex shape in the −Y axis direction.

For example, the mask sheet 44 may have a symmetrical shape about the horizontal central axis CL1 and the vertical central axis CL2. However, this is merely an example, and considering the purpose of use and a relationship with other elements, the mask sheet 44 may have any of various shapes.

Referring to FIGS. 9A and 9B, the thickness D441-1 of the hole area HA and a thickness D441-3 of the outer area SA may be less than a thickness D441-4 of a remaining area of the first body 441.

Referring to FIG. 9A, the thickness D441-1 of the hole area HA and a thickness D441-3 of the outer area SA may be substantially equal to as each other. For example, a surface of the first body 441 including the hole area HA and the outer area SA may be recessed. For example, as shown in FIG. 9A, a surface of the first body 441 may be recessed. For example, a surface of the first body 441 in the −Z axis direction may be recessed. In this structure, the first body 441 may be located not to cause a gap between the hole area HA and the display substrate DS.

Referring to FIG. 9B, the thickness D441-1 of the hole area HA may be less than a thickness D441-4 of a remaining area of the first body 441, and the thickness D441-3 of the outer area SA may be less than the thickness D441-1 of the hole area HA. However, top surfaces of the hole area HA and a remaining area of the first body 441 (e.g., surfaces in the +Z axis) may form a same plane. Accordingly, the first body 441 may be located not to cause a gap between the hole area HA and the display substrate DS.

In the structure of FIGS. 9A and 9B, the outer area SA may reduce a sharp physical property difference between the hole area HA and the remaining area. Accordingly, waves (or wrinkles) may be prevented from being generated in a mask sheet (e.g., the mask sheet 44 of FIG. 8) due to a physical property difference between the hole are HA and the remaining area.

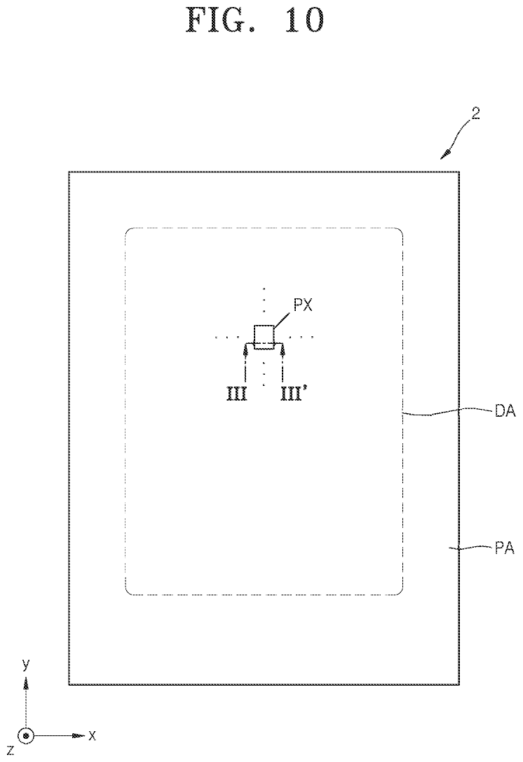

FIG. 10 is a plan view schematically illustrating a display apparatus manufactured by using a method of manufacturing a display apparatus, according to an embodiment.

Referring to FIG. 10, a display apparatus 2 manufactured according to an embodiment may include a display area DA and a peripheral area PA located outside the display area DA. The display apparatus 2 may provide an image through an array of pixels PX that are two-dimensionally arranged in the display area DA.

The peripheral area PA where an image is not provided may entirely or partially surround the display area DA. A driver or the like for providing an electrical signal or power to a pixel circuit corresponding to each of the pixels PX may be located in the peripheral area PA. A pad to which an electronic device, a printed circuit board, or the like may be electrically connected may be located in the peripheral area PA.

Although the display apparatus 2 includes an organic light-emitting diode (OLED) as a light-emitting element, the display apparatus 2 of the disclosure is not limited thereto. In another embodiment, the display apparatus 2 may be a light-emitting display apparatus including an inorganic light-emitting diode, for example, an inorganic light-emitting display apparatus. The inorganic light-emitting diode may include a PN diode including inorganic semiconductor-based materials. When a voltage is applied to a PN junction diode in a forward direction, holes and electrons may be injected, and energy generated by recombination of the holes and electrons may be converted into light energy to emit light of a certain color. The inorganic light-emitting diode may have a width of several to hundreds of micrometers, and in some embodiments, the inorganic light-emitting diode may be referred to as a micro-LED. In another embodiment, the display apparatus 2 may be a quantum dot light-emitting display apparatus.

The display apparatus 2 may be used as a display screen of not only a portable electronic device such as a mobile phone, a smartphone, a tablet personal computer (PC), a mobile communication terminal, an electronic organizer, an electronic book, a portable multimedia player (PMP), a navigation device, an ultra-mobile PC (UMPC), or the like, but also any of various products such as a television, a laptop computer, a monitor, an advertisement board, Internet of things (IoT) device, or the like. Also, the display apparatus 2 according to an embodiment may be used in a wearable device such as a smart watch, a watch phone, a glasses-type display, a head-mounted display (HMD), or the like. Also, the display apparatus 2 according to an embodiment may be applied to a center information display (CID) located on an instrument panel, a center fascia, or a dashboard of a vehicle, a room mirror display replacing a side-view mirror of a vehicle, or a display screen located on a back of a front seat for entertainment for a back seat of a vehicle.

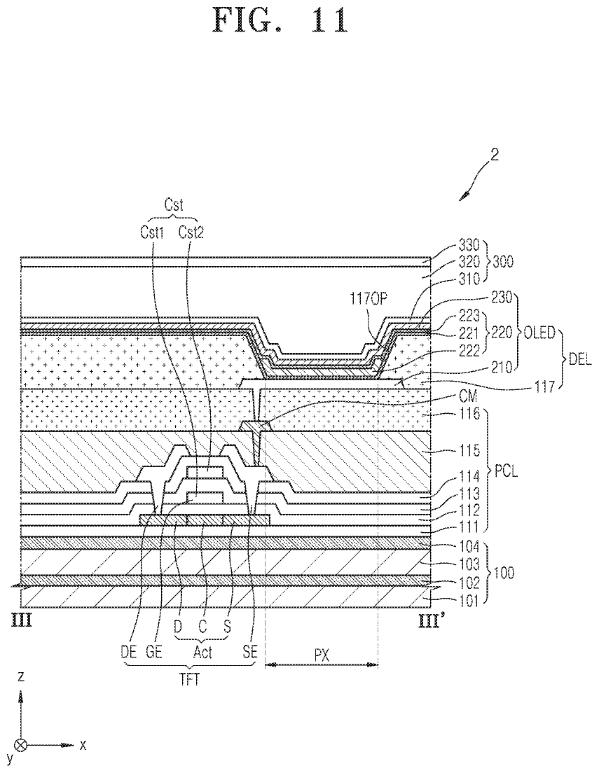

FIG. 11 is a cross-sectional view schematically illustrating a display apparatus manufactured by using a method of manufacturing a display apparatus, taken along line III-III′ of FIG. 10, according to an embodiment.

Referring to FIG. 11, the display apparatus 2 may have a structure in which the substrate 100, a pixel circuit layer PCL, a display element layer DEL, and an encapsulation layer 300 are stacked each other. The display substrate DS (see FIG. 1) may be formed by stacking at least one of the pixel circuit layer PCL, the display element layer DEL, and the encapsulation layer 300 on, for example, the substrate 100 in a process of manufacturing the display apparatus 2.

The substrate 100 may have a multi-layer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 which are sequentially stacked each other. Each of the first base layer 101 and the second base layer 103 may include at least one of polyimide (PI), polyethersulfone (PES), polyarylate, polyetherimide (PEI), polyethylene napthalate (PEN), polyethylene terephthalate (PET), polyphenylene sulfide (PPS), polycarbonate (PC), cellulose triacetate (TAC), cellulose acetate propionate (CAP), and the like. Each of the first barrier layer 102 and the second barrier layer 104 may include an inorganic insulating material such as silicon oxide, silicon oxynitride, and/or silicon nitride. The substrate 100 may be flexible.

The pixel circuit layer PCL may be located on the substrate 100. In FIG. 11, the pixel circuit layer PCL may include a thin-film transistor TFT, and a buffer layer 111, a first gate insulating layer 112, a second gate insulating layer 113, an interlayer insulating layer 114, a first planarization insulating layer 115, and a second planarization insulating layer 116 located under and/or over elements of the thin-film transistor TFT.

The buffer layer 111 may reduce or block penetration of a foreign material, moisture, or external air from the bottom of the substrate 100, and may planarize the substrate 100. The buffer layer 111 may include an inorganic insulating material such as silicon oxide, silicon oxynitride, silicon nitride, or the like, and may have a single or multi-layer structure including the above material.

The thin-film transistor TFT on the buffer layer 111 may include a semiconductor layer Act, and the semiconductor layer Act may include polysilicon. As another example, the semiconductor layer Act may include at least one of amorphous silicon, an oxide semiconductor, an organic semiconductor, and the like. The semiconductor layer Act may include a channel region C, and a drain region D and a source region S located on both sides of the channel region C. A gate electrode GE may overlap the channel region C.

The gate electrode GE may include a low-resistance metal material. The gate electrode GE may include at least one of a conductive material including molybdenum (Mo), aluminum (Al), copper (Cu), titanium (Ti), and the like, and may have a single or multi-layer structure including the above material.

The first gate insulating layer 112 between the semiconductor layer Act and the gate electrode GE may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). Zinc oxide (ZnOₓ) may be zinc oxide (ZnO) and/or zinc peroxide (ZnO₂).

The second gate insulating layer 113 may cover the gate electrode GE. The second gate insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), like the first gate insulating layer 112. Zinc oxide (ZnOₓ) may be zinc oxide (ZnO) and/or zinc peroxide (ZnO₂).

An upper electrode Cst2 of a storage capacitor Cst may be located on the second gate insulating layer 113. The upper electrode Cst2 may overlap the gate electrode GE that is located below the upper electrode Cst2. The gate electrode GE and the upper electrode Cst2 overlapping each other with the second gate insulating layer 113 therebetween may constitute the storage capacitor Cst. For example, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and the like and may have a single or multi-layer structure including the above material.

The interlayer insulating layer 114 may cover the upper electrode Cst2. The interlayer insulating layer 114 may include at least one of silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), and the like. Zinc oxide (ZnOₓ) may be zinc oxide (ZnO) and/or zinc peroxide (ZnO₂). The interlayer insulating layer 114 may have a single or multi-layer structure including the above inorganic insulating material.

Each of a drain electrode DE and a source electrode SE may be located on the interlayer insulating layer 114. The drain electrode DE and the source electrode SE may be respectively connected to the drain region D and the source region S through contact holes formed in insulating layers under the drain electrode DE and the source electrode SE. Each of the drain electrode DE and the source electrode SE may include a material having excellent conductivity. Each of the drain electrode DE and the source electrode SE may include a conductive material including at least one of molybdenum (Mo), aluminum (Al), copper (Cu), titanium (Ti), and the like and may have a single or multi-layer structure including the above material. In an embodiment, each of the drain electrode DE and the source electrode SE may have a multi-layer structure including Ti/Al/Ti.

The first planarization insulating layer 115 may cover the drain electrode DE and the source electrode SE. The first planarization insulating layer 115 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The second planarization insulating layer 116 may be located on the first planarization insulating layer 115. The second planarization insulating layer 116 may include a same material as that of the first planarization insulating layer 115, and may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, the like, or any combination thereof.

The display element layer DEL may be located on the pixel circuit layer PCL having the above structure. The display element layer DEL may include an organic light-emitting diode OLED as a display element (i.e., a light-emitting element), and the organic light-emitting diode OLED may have a structure in which a pixel electrode 210, an intermediate layer 220, and a common electrode 230 are stacked each other. The organic light-emitting diode OLED may emit, for example, red light, green light, or blue light, or may emit red light, green light, blue light, or white light. The organic light-emitting diode OLED may emit light through an emission area, and the emission area may be defined as the pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM located on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including at least one of silver (Ag), magnesium (Mg), aluminum (Al), platinum (Pt), palladium (Pd), gold (Au), nickel (Ni), neodymium (Nd), iridium (Jr), chromium (Cr), and the like, or a compound thereof. In another embodiment, the pixel electrode 210 may further include a film formed of ITO, IZO, ZnO, or In₂O₃ over/under the reflective film.

A pixel-defining film 117 having an opening 117OP through which a central portion of the pixel electrode 210 is exposed is located on the pixel electrode 210. The pixel-defining film 117 may include an organic insulating material and/or an inorganic insulating material. The opening 117OP may define the emission area of light emitted by the organic light-emitting diode OLED. For example, a size/width of the opening 117OP may correspond to a size/width of the emission area. Accordingly, a size and/or a width of the pixel PX may depend on a size and/or a width of the opening 117OP of the pixel-defining film 117.

The intermediate layer 220 may include an emission layer 222 formed to correspond to the pixel electrode 210. Each emission layer 222 may include a high molecular weight organic material or a low molecular weight organic material that emits light of a certain color. As another example, the emission layer 222 may include an inorganic light-emitting material or may include quantum dots.

In an embodiment, the intermediate layer 220 may include a first functional layer 221 and a second functional layer 223 respectively located under and over the emission layer 222. The first functional layer 221 may include, for example, a hole transport layer (HTL), or may include a hole transport layer and a hole injection layer (HIL). The second functional layer 223 that is a layer located on the emission layer 222 may include an electron transport layer (ETL) and/or an electron injection layer (EIL). The first functional layer 221 and/or the second functional layer 223 may be a common layer entirely covering the substrate 100, like the common electrode 230 described below.

The common electrode 230 may be located on the pixel electrode 210, and may overlap the pixel electrode 210. The common electrode 230 may be formed of a conductive material having a low work function. For example, the common electrode 230 may include at least one of a (semi)transparent layer including silver (Ag), magnesium (Mg), aluminum (Al) platinum (Pt), palladium (Pd), gold (Au), nickel (Ni), neodymium (Nd), iridium (Jr), chromium (Cr), lithium (Li), calcium (Ca), and an alloy thereof. As another example, the common electrode 230 may further include a layer formed of ITO, IZO, ZnO, or In₂O₃ on the (semi)transparent layer including the above material. The common layer 230 may be integrally formed to entirely cover the substrate 100.

The encapsulation layer 300 may be located on the display element layer DEL and may cover the display element layer DEL. The encapsulation layer 300 may include at least one inorganic encapsulation layer and at least one organic encapsulation layer. In an embodiment, in FIG. 11, the encapsulation layer 300 may include a first inorganic encapsulation layer 310, an organic encapsulation layer 320, and a second inorganic encapsulation layer 330 which are sequentially stacked each other.

Each of the first and second inorganic encapsulation layers 310 and 330 may include at least one inorganic material from among aluminum oxide, titanium oxide, tantalum oxide, hafnium oxide, zinc oxide, silicon oxide, silicon nitride, silicon oxynitride, and the like. The organic encapsulation layer 320 may include a polymer-based material. Examples of the polymer-based material may include an acrylic resin, an epoxy resin, polyimide, polyethylene, or the like. In an embodiment, the organic encapsulation layer 320 may include acrylate. The organic encapsulation layer 320 may be formed by curing a monomer or applying a polymer. The organic encapsulation layer 320 may be transparent.

Although not shown, a touch sensor layer may be located on the encapsulation layer 300, and an optical functional layer may be located on the touch sensor layer. The touch sensor layer may obtain coordinate information according to an external input, for example, a touch event. The optical functional layer may reduce a reflectance of light (external light) incident on a display apparatus, and/or improve color purity of light emitted from the display apparatus. In an embodiment, the optical functional layer may include a phase retarder and/or a polarizer. The phase retarder may be a film-type phase retarder or a liquid crystal coating-type phase retarder, and may include a λ/2 phase retarder and/or a λ/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in a certain arrangement. The phase retarder and the polarizer may further include a protective film.

An adhesive member may be located between the touch electrode layer and the optical functional layer. The adhesive member may be a general member well known in the art without limitation. The adhesive member may be a pressure sensitive adhesive (PSA).

According to embodiments, waves (or wrinkles) that may be generated when a mask sheet is tensioned and welded may be prevented, and interference between the mask sheet and a shield stick may be prevented, thereby improving the deposition quality of a deposition material.

The effects of the disclosure are not limited to the above-mentioned effects, and other effects not mentioned herein will be clearly understood by one of ordinary skill in the art from the appended claims.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display apparatus, the apparatus comprising:
a chamber;
a mask assembly located in the chamber to face a display substrate, and comprising at least one deposition area; and
a deposition source located in the chamber to face the mask assembly, and supplying a deposition material so that the deposition material passes through the at least one deposition area of the mask assembly and is deposited on the display substrate, wherein
the mask assembly comprises:
a mask frame comprising an opening area;
at least one shield stick intersecting the opening area; and
at least one mask sheet covering at least part of the opening area and at least partially overlapping the at least one shield stick, and each of the at least one mask sheet comprises:
a first body comprising a hole area comprising pattern holes and covering the at least one deposition area; and
a second body connected to the first body and fixed to the mask frame, and a maximum width of the first body is greater than a maximum width of the second body.

2. The apparatus of claim 1, wherein
the at least one mask sheet comprises an overlapping area overlapping the at least one shield stick in a plan view, and
the overlapping area has a convex shape in a plan view.

3. The apparatus of claim 1, wherein the hole area comprises:
a first hole area overlapping the at least one shield stick in a plan view; and
a second hole area not overlapping the at least one shield stick in a plan view.

4. The apparatus of claim 3, wherein the first hole area has a convex shape.

5. The apparatus of claim 3, wherein a number of pattern holes per unit area in the first hole area and a number of pattern holes per unit area in the second hole area are substantially equal to each other.

6. The apparatus of claim 3, wherein, in a plan view, sizes of pattern holes provided in the first hole area and sizes of pattern holes provided in the second hole area are substantially equal to each other.

7. The apparatus of claim 3, wherein a number of pattern holes per unit area provided in the first hole area gradually decreases outward.

8. The apparatus of claim 3, wherein, in a plan view, sizes of pattern holes provided in the first hole area gradually decrease outward.

9. The apparatus of claim 1, wherein a thickness of the hole area is less than a thickness of an area where the pattern holes are not provided.

10. The apparatus of claim 1, wherein
the first body further comprises an outer area located outside the hole area and overlapping the at least one shield stick in a plan view, and
a thickness of the hole area and a thickness of the outer area are less than a thickness of a remaining area of the first body.

11. The apparatus of claim 10, wherein, in a plan view, the outer area has a convex portion.

12. A method of manufacturing a display apparatus, the method comprising:
locating a display substrate and a mask assembly in a chamber; and
depositing a deposition material on the display substrate by allowing the deposition material to pass through the mask assembly, wherein
the mask assembly comprises:
a mask frame comprising an opening area; and
at least one mask sheet covering at least part of the opening area, and each of the at least one mask sheet comprises:
a first body comprising a hole area comprising pattern holes; and
a second body connected to the first body and fixed to the mask frame, and
a maximum width of the first body is greater than a maximum width of the second body.

13. The method of claim 12, wherein, in a plan view, the first body has a convex shape.

14. The method of claim 12, wherein, in a plan view, the hole area has a convex shape.

15. The method of claim 14, wherein a number of pattern holes per unit area in the hole area is uniform.

16. The method of claim 14, wherein, in a plan view, sizes of the pattern holes in the hole area are same.

17. The method of claim 14, wherein a number of pattern holes per unit area in an outer portion of the hole area is less than a number of pattern holes in a central portion of the hole area.

18. The method of claim 14, wherein sizes of pattern holes in an outer portion of the hole area are less than sizes of pattern holes in a central portion of the hole area.

19. The method of claim 12, wherein a thickness of the hole area is less than a thickness of an area where the pattern holes are not provided.

20. The method of claim 12, wherein
the first body further comprises an outer area located outside the hole area, and
a thickness of the hole area and a thickness of the outer area are less than a thickness of a remaining area of the first body.
